(19) United States
(12) Patent Application Publication
(10) Pub. No.: US 2008/0000519 A1
(43) Pub. Date: Jan. 3, 2008

(54) Solar Cell Device and Method for Manufacturing the Same

(75) Inventor: Hiroaki Takahashi, Ise-shi (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 11/572,703

(22) PCT Filed: Jul. 29, 2005
(86) PCT No.: PCT/JP05/13937

§ 371 Date: Jan. 25, 2007

(30) Foreign Application Priority Data
Jul. 29, 2004 (JP) 2004-221177

(51) Int. Cl. H01L 31/0224; H01L 31/068

(52) U.S. Cl. 136/252

(57) ABSTRACT

The present invention provides a solar cell device 1 in which at least a part of a collecting electrode 10 provided on the back surface of a semiconductor substrate 2 contains a semiconductor element constituting the semiconductor substrate 2 and a content ratio thereof is set higher in a side of the collecting electrode 10 in contact with the semiconductor substrate 2 than in an outer surface side thereof. According to the present invention, a difference in the thermal expansion coefficients at an interface between the semiconductor substrate 2 and the collecting electrode 10 can be reduced, so that even when the thickness of the semiconductor substrate 2 is reduced, warping of the solar cell device 1 can be sufficiently reduced. In addition, while the conductivity of the collecting electrode 10 is maintained in a good range, a BSF region 11 with a uniform and sufficient thickness can be formed on the back side of the semiconductor substrate 2, so that the solar cell device 1 of the present invention is also excellent in characteristics such as conversion efficiency.

### TECHNICAL FIELD

The present invention relates to a solar cell device and a method for manufacturing the same.

### BACKGROUND ART

FIG. 11 is a plan view of a front surface (light receiving surface) of a conventional solar cell device 101, FIG. 12 is a plan view of a back surface of the solar cell device 101 of FIG. 11, and FIG. 13 is an enlarged sectional view of an internal structure of the solar cell device 101 of FIG. 11. Referring to these drawings, the conventional solar cell device 101 includes a p-type semiconductor substrate 102 that is, for example, in a plate shape with a size of a 100 to 150 mm square and a thickness of 0.3 to 0.4 mm, made of polycrystal or single-crystal silicon doped with a p-type impurity such as boron (B) or aluminum (Al), etc.

A region from the surface of the semiconductor substrate 102 to the depth of 0.2 to 0.5 μm is formed as a diffusion layer 103 in which an n-type impurity such as phosphorus (P) is diffused, and at an interface with a p-type region under the diffusion layer, p-n junction is formed. When the p-n junction is irradiated with light from the surface of the semiconductor substrate 2, due to a so-called photovoltaic effect, electron-hole pairs are generated and generate photovoltaic power. The diffusion layer 103 is formed, for example, by heating the p-type semiconductor substrate 102 in a diffusion furnace in the presence of a compound such as phosphorus oxychloride, etc., which composes the n-type impurity to diffuse the n-type impurity in the entire surface of the semiconductor substrate 102 and then removing the diffusion layer formed on the side surface and the back surface of the semiconductor substrate 102.

On the surface of the semiconductor substrate 102, a front electrode 104 is provided. The front electrode 104 includes a plurality of finger electrodes 105 provided in parallel to each other and two busbar electrodes 106 for external connection provided in parallel to each other crossing the finger electrodes 105 so as to connect the finger electrodes 105 on the surface of the semiconductor substrate 102. A region other than the front electrode 104 on the surface of the semiconductor substrate 102 is covered by an antireflective coating 107 made of silicon nitride or silicon oxide, etc. The antireflective coating 107 is formed by, for example, plasma CVD, and preferably, it also has a function as a passivation film.

On the back surface of the semiconductor substrate 102, a back electrode 108 is formed. The back electrode 108 includes two extracting electrodes 109 for external connection provided in parallel to each other and a collecting electrode 110 on the back surface of the semiconductor substrate 102. The collecting electrode 110 is provided so as to cover generally entire area of the back surface of the semiconductor substrate 102 except for regions in which the extracting electrodes 109 are formed and a peripheral portion of the semiconductor substrate 102. The front electrode 104 and the back electrode 108 are formed by printing a paste of an electrode material including a metal element on the surface and the back surface of the semiconductor substrate 102 in predetermined planar shapes by, for example, screen printing, drying it, and then firing it, and when the following steps (i) through (iv) are followed, the front electrode and the back electrode can be simultaneously formed by one firing.

(i) A paste of an electrode material for forming the collecting electrode 110 is printed on the back surface of the semiconductor substrate 102 and dried to form a layer of the electrode material corresponding to the planar shape of the collecting electrode 110.

(ii) A paste of an electrode material for forming the extracting electrodes 109 is printed on the back surface of the semiconductor substrate 102 and dried to form layers of the electrode material corresponding to the planar shapes of the extracting electrodes 109.

(iii) A paste of an electrode material for forming the front electrode 104 is printed on the surface of the semiconductor substrate 102 and dried to form a layer of the electrode material corresponding to a planar shape of the front electrode 104, that is, the finger electrodes 105 and the bus bar electrodes 106.

(iv) The semiconductor substrate 102 on which the layers of the electrode materials were formed is fired to form the finger electrodes 105 and the bus bar electrodes 106 as the front electrode 104, and the extracting electrodes 109 and the collecting electrode 110 as the back electrode 108.

It is preferable that the layer of the electrode material formed according to (i) and the layer of the electrode material formed according to (ii) are brought into contact with each other without a gap or the layer of the electrode material of (ii) is stacked later to a part (for example, peripheral portion) of the layer of the electrode material of (i) formed earlier to obtain an excellent conductive connection of these after firing. Preferably, the metal elements for forming the bus bar electrodes 106 and the extracting electrodes 109 are both silver or the like which has excellent conductivity and excellent solder wettability for easy connection to wiring (lead wires) for external connection.

On the other hand, as a metal element for forming the collecting electrode 110, aluminum which has excellent conductivity and functions as a p-type impurity with respect to silicon is preferable. When a layer of an electrode material formed by printing a paste of an electrode material containing aluminum as a metal element is fired at the step of (iv), a part of the aluminum in the layer is thermally diffused into the semiconductor substrate 102, and on the back side of the semiconductor substrate 102, a back side field region (BSF region) 111 that is a so-called p⁺ type region in which aluminum as a p-type impurity is diffused at high concentration is formed.

The BSF region 111 functions to reduce the ratio of minority carriers (electrons) which have been generated by p-n junction according to light irradiation and injected into the p-type region to reach the collecting electrode 110 and be re-combined and lost, so that the photocurrent density J_{c} of the solar cell device 101 can be improved. In the BSF region 111, the density of the minority carriers (electrons) is lowered, so that the open voltage V_{oc} of the solar cell device 101 can also be improved. Therefore, by providing the BSF region 111, the characteristics (conversion efficiency, etc.) of the solar cell device can be improved.

However, when the collecting electrode 110 is made of aluminum alone, based on a difference in thermal expansion coefficient unique to materials between the collecting electrode 110 and the semiconductor substrate 102 made of polycrystal or single-crystal silicon, at the time of cooling after firing, the collecting electrode 110 more greatly contracts than the semiconductor substrate 102, and as a result, as shown in FIG. 10, the solar cell device 101 warps so as to project toward the semiconductor substrate 102 side. This is caused by the thermal expansion coefficient of aluminum 10 times as large as that of silicon.

If the solar cell device 101 warps, for example, when the manufactured solar cell device 101 is stored in a cassette for transportation or storage by using an automated machine or when the solar cell device is handled in a process next to the manufacturing process, a handling failure easily occurs. Therefore, cracks and fractures of the solar cell device 101 frequently occur and the production yield of the solar cell device 101 significantly lowers. Therefore, to prevent warping of the solar cell device 101, it has been proposed that the paste of the electrode material for forming the collecting electrode 110 is mixed with silicon at a ratio of 0.5 through 50 parts by weight to 100 parts by weight of aluminum (Patent document 1).

When the paste of the electrode material for forming the collecting electrode 110 is mixed with not only aluminum but also silicon as a semiconductor element for forming the semiconductor substrate 102 in the above-described range, it becomes possible to reduce the difference in the thermal expansion coefficient between the collecting electrode 110 formed by printing, drying, and then firing the paste and the semiconductor substrate 102 made of polycrystal or single-crystal silicon and to reduce the warping of the solar cell device 101.

Patent document 1: Japanese Unexamined Patent Publication No. 2001-313402

### DISCLOSURE OF THE INVENTION

### Problem to be Solved by the Invention

Recently, it has been studied the thickness of the semiconductor substrate 102 is made smaller than the current thickness, that is, in detail, the thickness of the semiconductor substrate 102 is set to be not more than 300 μm, in order to increasing the number of semiconductor substrates 102 formed from one silicon ingot by minimizing the amount of silicon used, and to raising the production yield of the solar cell device 101. However, as the thickness of the semiconductor substrate 102 is reduced, the rigidity of the semiconductor substrate 102 lowers, so that even if the collecting electrode 110 is formed by using the paste described in Patent document 1, the effect of reducing the warping of the solar cell device 101 is reduced and the warping becomes great.

By increasing the content of silicon in the paste, the effect of reducing the warping of the solar cell device 101 can be improved. However, the aluminum content in the paste is relatively reduced and the conductivity of the collecting electrode 110 formed by firing lowers, so that this poses a new problem of deterioration of the characteristics of the solar cell device 101. If the thickness of the collecting electrode 110 is reduced, the effect of reducing the warping of the solar cell device 101 can be improved. However, when the paste is fired to form the collecting electrode 110, on the back side of the semiconductor substrate 102, the amount of aluminum diffused from the paste is short, and on the back side, the BSF region 111 which has a uniform and sufficient thickness cannot be formed, so that this poses a problem of deterioration of the characteristics of the solar cell device 101. An object of the invention is to provide a solar cell device whose warping can be sufficiently reduced and which has excellent characteristics such as conversion efficiency even if the thickness of the semiconductor substrate is reduced, and a method for efficiently manufacturing this solar cell device.

### Means for Solving the Problem

A solar cell device of the present invention includes a planar semiconductor substrate having a front surface and a back surface, and an electrode provided on generally entire area of the surface of the back surface of the semiconductor substrate, wherein at least a part in a thickness direction of the electrode contains a semiconductor element constituting the semiconductor substrate and a content ratio of the semiconductor element is set greater in a side of the electrode in contact with the semiconductor substrate than in an outer surface side of the electrode.

It is preferable that the content ratio of the semiconductor element in the electrode is discontinuously changed in the thickness direction of the electrode. It is more preferable that the content ratio of the semiconductor element is discontinuously and monotonously reduced from the side in contact with the semiconductor substrate toward the outer surface side. It is preferable that the electrode is formed by laminating two or more electrode materials with different content ratios of the semiconductor element in order on generally entire area of the back surface of the semiconductor substrate and firing these. It is preferable that the semiconductor substrate is a silicon substrate, and the electrode is an aluminum electrode. It is preferable that the thickness of the electrode is 10 to 30 μm.

A method for manufacturing a solar cell device of the present invention includes the steps of: forming a lamination of two or more electrode materials with different content ratios of a semiconductor element by applying in order a paste of two or more electrode materials with different content ratios of the semiconductor element on generally entire area of the back surface of the semiconductor substrate and drying these; and forming a electrode by firing and unifying the lamination for manufacturing the solar cell device of the invention.

### EFFECTS OF THE INVENTION

According to the present invention, in the electrode, the content ratio of the semiconductor element is set greater in the side in contact with the semiconductor substrate than in the outer surface side, so that the difference in the thermal expansion coefficient at an interface between the semiconductor substrate and the electrode can be made small. Therefore, even if the thickness of the semiconductor substrate is reduced, warping of the solar cell device can be sufficiently reduced.

The content ratio of the semiconductor element in the electrode is set smaller in the outer surface side than in the side in contact with the semiconductor substrate (including the case where the outer surface side does not contain the semiconductor element, the same applies to the description given below), so that the rise in the content ratio of the semiconductor element in the whole of the electrode can be suppressed and the conductivity of the electrode can be maintained within a good range.

Along with this, in particular, when the semiconductor substrate is a silicon substrate and the electrode is an aluminum electrode, when a layer of an electrode material is fired for forming the electrode, it is also possible that aluminum constituting the electrode is more satisfactorily thermally diffused to the back side in contact with the layer of the electrode material of the semiconductor substrate to form a BSF region having a uniform and sufficient thickness on the back side. This is because, by distributing the content ratio of silicon in the electrode as described above, the warping of the solar cell device can be sufficiently reduced even without reducing the thickness of the electrode, and a sufficient amount of aluminum can be diffused from the paste for forming the electrode to the back side of the semiconductor substrate at the time of firing, and silicon and aluminum at the time of firing assume an eutectic crystal state with a melting temperature (melting temperature: 557° C. lower than a melting temperature (660° C.) of simple aluminum and easily become due to the heat of firing a melt whose diffusion speed into the semiconductor substrate is higher than that of simple aluminum in a solid state.

That is, in the side in contact with the semiconductor substrate of the layer of the electrode material, the content ratio of silicon as the semiconductor element is set to be high, on the surface on the side of the layer of the electrode material in contact with the semiconductor substrate, the eutectic crystal state is assumed, and due to the heat of firing, points where the melt is easily produced are generated more than usual, so that aluminum is more smoothly thermally diffused into the semiconductor substrate through the points to form a BSF region with a uniform and sufficient thickness. Therefore, the solar cell device of the present invention becomes excellent in characteristics such as conversion efficiency, etc., due to the combination of conductivity of the electrode maintained within a good range and the BSF region with a uniform and sufficient thickness formed on the backside of the semiconductor substrate. The content ratio of the semiconductor element in the electrode can be discontinuously changed in the thickness direction of the electrode.

Particularly, when the content ratio of the semiconductor element is discontinuously and monotonously reduced from the side in contact with the semiconductor substrate toward the outer surface side, the thermal expansion coefficient of the electrode can be monotonously changed from the side in contact with the semiconductor substrate toward the outer surface side, so that the effect of reducing the warping of the solar cell device can be further improved. In the solar cell device of the present invention, for reducing the number of manufacturing steps and forming a electrode including layers which are more firmly unified, it is preferable that layers of two or more electrode materials with different content ratios of the semiconductor element are formed by laminating the layers in order and then firing them.

As described above, when a silicon substrate is used as the semiconductor substrate and an aluminum electrode is used as the electrode, at the time of firing, a BSF region with a uniform and sufficient thickness can be formed by thermally diffusing aluminum into the back side of the semiconductor substrate, so that the characteristics of the solar cell device can be further improved. When the thickness of the electrode is 10 to 30 μm, the effect of reducing the warping of the solar cell device can be further improved, and the characteristics of the solar cell device can be further improved. According to the manufacturing method of the present invention, the electrode is formed by laminating in order and then firing two or more electrode materials with different content ratio of a semiconductor element, so that the number of manufacturing steps of the solar cell device can be reduced, and a electrode in which the respective regions are more firmly unified can be formed.

### BRIEF DESCRIPTION OF THE DRAWINGS

FIG. 1 is a plan view showing a front surface of a solar cell device as an embodiment of the invention;

FIG. 2 is a plan view showing a back surface of the solar cell device of FIG. 1;

FIG. 3 is an enlarged sectional view showing an internal structure of the solar cell device of FIG. 1;

FIG. 4 is an enlarged sectional view showing a step of manufacturing the solar cell device of FIG. 1;

FIG. 5 is an enlarged sectional view showing a step of manufacturing the solar cell device of FIG. 1;

FIG. 6 is an enlarged sectional view showing a step of manufacturing the solar cell device of FIG. 1;

FIG. 7 is an enlarged sectional view showing a step of manufacturing the solar cell device of FIG. 1;

FIG. 8 is an enlarged sectional view showing a step of manufacturing the solar cell device of FIG. 1;

FIG. 9 is an enlarged sectional view showing a step of manufacturing the solar cell device of FIG. 1;

FIG. 10 is a front view for explaining a method for measuring warping amounts of solar cell devices manufactured according to examples and comparative examples;

FIG. 11 is a plan view showing a front surface of a conventional solar cell device;

FIG. 12 is a plan view showing a back surface of the solar cell device of FIG. 11; and

FIG. 13 is an enlarged sectional view showing an internal structure of the solar cell device of FIG. 11.

### BEST MODE FOR CARRYING OUT THE INVENTION

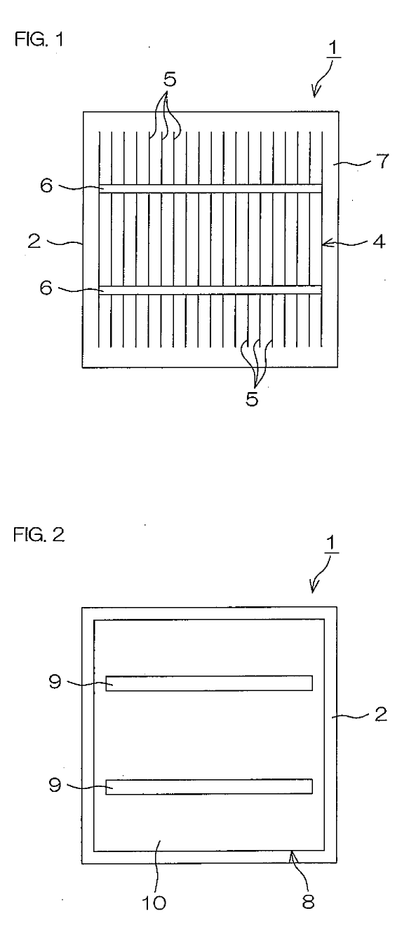

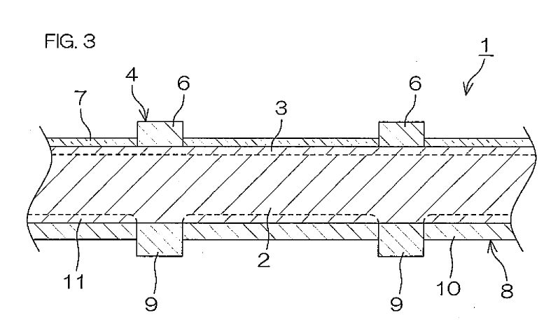

FIG. 1 is a plan view showing a front surface (light receiving surface) of a solar cell device 1 as an embodiment of the invention, FIG. 2 is a plan view showing a back surface of the solar cell device of FIG. 1, and FIG. 3 is an enlarged sectional view showing an internal structure of the solar cell device 1 of FIG. 1.

Referring to these drawings, the solar cell device 1 of this example includes a p-type semiconductor substrate 2 which is in a plate shape with a size of a 100 to 150 mm square and a thickness not more than 300 μm, made of polycrystal or single-crystal silicon (Si), etc., and doped with a p-type impurity such as boron (B) or gallium (Ga). A region from the surface of the semiconductor substrate 2 to a depth of 0.2 to 0.5 μm is an n-type diffusion layer 3 in which an n-type impurity such as phosphorus (P) is diffused, and at an interface with a p-type region under the n-type diffusion layer, a p-n junction is formed. When the p-n junction is irradiated with light from the surface of the semiconductor substrate 2, due to a so-called photovoltaic effect, electron-hole pairs are generated and generate photovoltaic power.

On the surface of the semiconductor substrate 2, a front electrode 4 is provided. The front electrode 4 includes a plurality of finger electrodes 5 provided in parallel to each other and two bus bar electrodes 6 for external connection provided in parallel to each other so as to cross the finger electrodes 5 to connect the finger electrodes 5 on the surface of the semiconductor substrate 2. The front electrode 4 is formed by printing a paste of an electrode material containing a metal element into a predetermined planar shape by means of, for example, screen printing, drying and firing the paste.

As a metal element for forming the surface side electrode 4, for easy connection to wiring (lead wire) for external connection, silver or the like which has excellent solder wettability and excellent conductivity is preferable. A region of the surface of the semiconductor substrate 2 except for the region in which the front electrode 4 is formed is coated with an antireflective coating 7 made of silicon nitride, silicon oxide, or the like. It is preferable that the antireflective coating 7 is formed by, for example, plasma CVD, and also has a function as a passivation film.

On the back surface of the semiconductor substrate 2, a back electrode 8 is formed. The back electrode 8 includes two extracting electrodes 9 for external connection, provided in parallel to each other on the back surface of the semiconductor substrate 2, and a collecting electrode 10. The collecting electrode 10 is provided so as to cover generally entire area of the back surface of the semiconductor substrate 2 except for the regions in which the extracting electrodes 9 are formed and the peripheral portion of the semiconductor substrate 2. The electrodes 9 and 10 are formed, in the same manner as the front electrode 4, by printing a paste of an electrode material containing a metal element into a predetermined planar shape by means of screen printing, etc., drying and firing the paste. As the metal element for forming the extracting electrodes 9, for easy connection to wiring (lead wire) for external connection, silver or the like which has excellent wettability and excellent conductivity is preferable.

On the other hand, as a metal element for forming the collecting electrode 10, aluminum which has excellent conductivity and functions as a p-type impurity with respect to silicon is preferable. When a layer of the electrode material formed by printing the paste of the electrode material containing aluminum as a metal element is fired, a part of the aluminum in the layer is thermally diffused into the semiconductor substrate 2 and a BSF region 11 as a p⁺ type region in which aluminum as a p-type impurity is diffused at a high concentration is formed on the back side of the semiconductor substrate 2.

The BSF region 11 functions to reduce the amount of minority carriers (electrons) generated by the p-n junction according to light irradiation and injected into the p-type region to reach the collecting electrode 110 and be re-combined and lost, so that the photocurrent density J_{c} of the solar cell device 1 can be improved. In the BSF region 11, the density of the minority carriers (electrons) is reduced, so that it is also possible to improve the open voltage V_{oc} of the solar cell device 1. Therefore, by providing the BSF region 11, the characteristics of the solar cell device 1 can be improved.

The collecting electrode 10 formed of aluminum contains silicon as a semiconductor element constituting the semiconductor substrate 2, and the silicon content ratio is set higher in the side of the collecting electrode 10 in contact with the semiconductor substrate 2 than in the outer surface side. Therefore, even when the thickness of the semiconductor substrate 2 is set to be not more than 300 μm, it becomes possible to reduce a difference in the thermal expansion coefficients at an interface between the semiconductor substrate 2 and the collecting electrode 10 and sufficiently reduce the warping.

The BSF region 11 formed on the back side of the semiconductor substrate 2 in contact with the collecting electrode 10 can also be formed to have a uniform and sufficient thickness. The reason for this is that, by distributing the silicon content ratio in the collecting electrode 10 as described above, even if the thickness is not reduced, warping of the solar cell device 1 can be sufficiently reduced, a sufficient amount of aluminum can be diffused into the back side of the semiconductor substrate 2 when firing the paste for forming the collecting electrode 10, and silicon and aluminum during firing assume an eutectic crystal state with a melting temperature (melting temperature: 557° C.) lower than the melting temperature (660° C.) of simple aluminum, and due to the heat of firing, easily become a melt whose diffusion speed into the semiconductor substrate 2 is higher than that of simple aluminum in a solid state.

That is, when the content ratio of silicon as a semiconductor element is set greater in the side of the layer of the electrode material in contact with the semiconductor substrate 2 on the surface on the side of the layer of the electrode material in contact with the semiconductor substrate 2, points which assume the eutectic crystal state and easily produce the melt due to the heat of firing are generated more than usual, so that through these points, aluminum is more smoothly thermally diffused into the semiconductor substrate 2 and forms the BSF region 11 with a uniform and sufficient thickness.

In addition, the content ratio of silicon is set smaller in the outer surface side of the collecting electrode 10 than in the side in contact with the semiconductor substrate 2, so that it is also possible to suppress the rise in the content ratio of silicon in the entire collecting electrode 10 and maintain the conductivity of the collecting electrode 10 in a good range. Therefore, in the solar cell device 1, due to realization of both of maintaining of the conductivity of the collecting electrode 10 in a good range and formation of the BSF region 11 with a uniform and sufficient thickness on the back side of the semiconductor substrate 2, the characteristics such as conversion efficiency also become excellent. The content ratio of silicon in the collecting electrode can be discontinuously changed in the thickness direction of the collecting electrode.

Particularly, when the content ratio of silicon in the collecting electrode 10 is discontinuously and monotonously reduced toward the outer surface side from the side in contact with the semiconductor substrate 2, the thermal expansion coefficient of the collecting electrode can be monotonously changed from the side in contact with the semiconductor substrate 2 toward the outer surface side. Therefore, the effect of reducing the warping of the solar cell device 1 can be further improved.

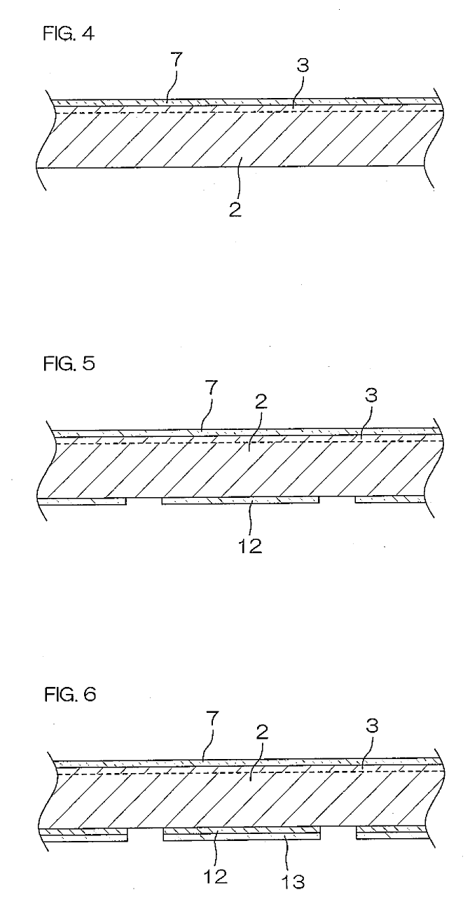

FIG. 4 through FIG. 9 are enlarged sectional views showing steps of manufacturing the solar cell device 1 shown in FIG. 1 through FIG. 3. Herein, a case where the collecting electrode 10 is formed by laminating two layers 12 and 13 of the electrode materials is described. The layer 13 of the electrode material is a layer with a silicon content ratio made smaller than that of the layer 12 of the electrode material. By firing and unifying both of these layers, the collecting electrode 10 in which the content ratio of silicon is set larger in the side in contact with the semiconductor substrate 2 than in the outer surface side can be formed. To manufacture the solar cell device 1, a semiconductor substrate 2 is prepared which is in a plate shape with a size of a 100 to 150 mm square and a thickness not more than 300 μm, made of polycrystal or single-crystal silicon, etc., and doped with a p-type impurity such as boron or gallium, etc. (FIG. 4)

As the semiconductor substrate 2, a single-crystal or polycrystal silicon substrate with a doped amount of a p-type impurity of 1×10¹⁶ through 1×10¹⁸ atoms in terms of the number of atoms of the p-type impurity per unit volume (atoms/cm³) and a specific resistance adjusted to 1.0 to 2.0 Ω·cm is preferable. The single-crystal silicon substrate can be formed by slicing into a plate shape a silicon ingot produced by a so-called pulling-up method in which silicon and a p-type impurity are melted and crystal-grown while gradually pulled up, and a polycrystal silicon substrate can be formed by similarly slicing into a plate shape a silicon ingot produced by a so-called casting method in which silicon and a p-type impurity are melted in a casting mold and are then gradually cooled.

The latter polycrystal silicon substrate can be mass-produced, and is more excellent in terms of manufacturing cost than the single-crystal silicon substrate. That is, the polycrystal silicon ingot produced by the casting method is large in size and can be produced in a short period of time, so that by slicing the polycrystal silicon ingot, mass production of the polycrystal silicon substrate is realized. It is preferable that the entire surface of the sliced silicon substrate is slightly etched by using hydrofluoric acid, fluoro-nitric acid, alkali, etc., for removing damaged layers and cleaning the surface. The entire surface of the etched silicon substrate may be further etched by dry-etching or wet-etching to form fine unevenness on the entire surface.

A region from the surface of the semiconductor substrate 2 to the depth of 0.2 to 0.5 μm is formed as an n-type diffusion layer 3 in which an n-type impurity such as phosphorus is diffused, and at an interface with a p-type region under the n-type diffusion layer, a p-n junction is formed. The diffusion layer 3 is formed by heating the semiconductor substrate 2 in a diffusion furnace in the presence of a compound that constitutes an n-type impurity such as phosphorous oxychloride to diffuse the n-type impurity into the entire surface of the semiconductor substrate 2 and then removing diffusion layers formed on the side surface and the back surface of the semiconductor substrate 2.

It is preferable that the diffused amount of the n-type impurity in the diffusion layer 3 is adjusted so that the sheet resistance of the surface of the diffusion layer 3 becomes 30 to 300Ω/□. To remove the diffusion layers formed on the side surface and the back surface of the semiconductor substrate 2, the surface of the semiconductor substrate 2 is etched by using a mixed solution of hydrofluoric acid and nitric acid while covered by a resist film with resistance against hydrofluoric acid. It is preferable that the etched semiconductor substrate 2 is cleaned by pure water after removing the resist film.

Next, an antireflective coating 7 made of silicon nitride, silicon oxide, etc., is formed on the surface of the semiconductor substrate 2 on which the diffusion layer 3 was formed. The antireflective coating 7 made of silicon nitride can be formed by a so-called plasma CVD method in which, for example, in a mixed gas of silane (SiH₄) and ammonia (NH₃), glow discharge is generated to turn these substances into plasmas and the substances are deposited on the surface of the semiconductor substrate 2 on which the diffusion layer 3 was formed.

When the antireflective coating 7 made of silicon nitride is formed by the plasma CVD method in the presence of hydrogen (H₂), passivation treatment can be performed so that terminal bonds of silicon present on the surface of the silicon substrate as the semiconductor substrate 2 are terminated by hydrogen, and as a result the antireflective coating can be made to also function as a passivation film as well as the antireflection function, and the characteristics of the solar cell device 1 can be further improved. It is preferable that the antireflective coating 7 has a refractive index of 1.8 to 2.3 for reducing the difference in refractive indexes between the same and the silicon substrate as the semiconductor substrate 2. It is preferable that the thickness of the antireflective coating 7 is 500 to 1000 Å for improving the transmittance while preventing interference fringes.

Next, on the back surface of the semiconductor substrate 2, a paste of an electrode material containing aluminum as a metal element and silicon as a semiconductor element is printed by screen printing or the like into a predetermined planar shape, that is, a planar shape covering generally entire area of the back surface of the semiconductor substrate 2 except for the regions in which the extracting electrodes 9 are formed and the peripheral portion of the semiconductor substrate 2, and then dried to form the layer 12 of the electrode material of the two layers 12 and 13 of the electrode materials for forming the collecting electrode 10 (FIG. 5). As the paste of the electrode material to be used herein, a paste of a mixture of 0.5 to 50 parts by weight of silicon powder, 10 to 30 parts by weight of an organic solvent, and 0.1 to 5 parts by weight of an organic binder such as a resin mixed with 100 parts by weight of aluminum powder is used. The organic binder is blended as appropriate for improving the adhesiveness of the layer 12 of the electrode material to the semiconductor substrate 2.

If the content ratio of silicon in the layer 12 of the electrode material is less than 0.5 parts by weight, there is a possibility that the effect of reducing the difference in the thermal expansion coefficient from the semiconductor region 2 and preventing warping of the solar cell device 1 cannot be sufficiently obtained. In addition, there is a possibility that the effect of generating many points which easily produce a melt due to the heat of firing on the surface of the layer 12 of the electrode material on the side in contact with the semiconductor substrate 2 and smoothly thermally diffusing aluminum into the semiconductor substrate 2 though the points becomes insufficient, and the BSF region 11 with a uniform and sufficient thickness cannot be formed on the back side of the semiconductor substrate 2.

If the content ratio of silicon in the layer 12 of the electrode material is more than 50 parts by weight, even when a layer 13 of the electrode material whose content ratio of silicon is smaller is laminated, the effect of maintaining the conductivity of the collecting electrode 10 in a good range by suppressing the rise in the content ratio of silicon in the whole of the collecting electrode 10 becomes insufficient, and on the side of the collecting electrode 10 in contact with the semiconductor substrate 2, a region whose conductivity is lower is generated and obstructs satisfactory power collection of the collecting electrode 10, so that the effect of improving the characteristics of the solar cell device 1 may not be sufficiently obtained. It is more preferable that the content ratio of silicon in the layer 12 of the electrode material is 20 to 40 parts by weight in the above-described range with respect to 100 parts by weight of aluminum.

Next, on the layer 12 of the electrode material, the paste of the electrode material whose content ratio of silicon is small is printed in the same manner by screen printing or the like into the same planar shape and dried to laminate the layer 13 of the electrode material of the two layers 12 and 13 of the electrode materials forming the collecting electrode 10 (FIG. 6). As the paste of the electrode material to be used herein, a paste of a mixture of the same ingredients as those of the paste of the layer 12 of the electrode material except that the paste has a smaller blending amount of silicon powder is used. The organic binder is blended as appropriate for improving the adhesiveness of the layer 13 of the electrode material to the layer 12 of the electrode material.

Although the content ratio of silicon in the layer 13 of the electrode material is required to be smaller than the content ratio of silicon in the layer 12 of the electrode material, considering as much improvement on the effect as possible for suppressing the rise in the content ratio of silicon in the whole of the collecting electrode 10 and maintaining the conductivity of the collecting electrode 10 in a good range, the content ratio of silicon in the layer 13 is preferably smaller by 10 parts by weight or more than the content ratio of silicon in the layer 12 of the electrode material. Particularly, it is preferable that the electrode material layer 13 does not contain silicon, that is, the content of silicon with respect to 100 parts by weight of aluminum is 0 parts by weight.

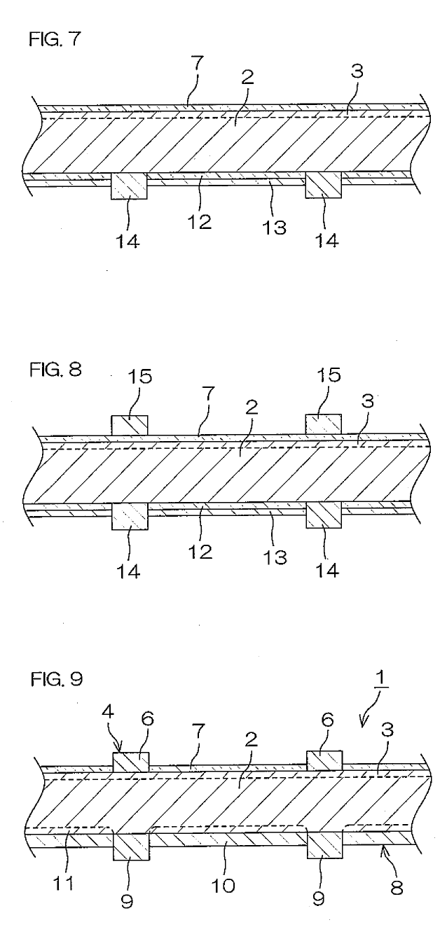

Next, on the back surface of the semiconductor substrate 2, in a region in which the layers 12 and 13 of the electrode materials are not formed, the paste of the electrode material for forming the extracting electrodes 9 containing silver is printed into predetermined planar shapes by screen printing or the like and dried to form the layers 14 of the electrode material for forming the extracting electrodes 9 (FIG. 7). It is preferable that, for good conductive connection between the fired extracting electrodes 9 and the collecting electrode 10, the layers 14 of the electrode material are brought into contact with the layers 12 and 13 of the electrode materials previously formed without gaps, or their planar shapes are set so that the layers 14 of the electrode material can be overlapped with a part (for example, peripheral portion) of the layers 12 and 13 of the electrode materials previously formed.

As the paste of the electrode material to be used herein, a paste of a mixture of 10 to 30 parts by weight of an organic solvent and 0.1 to 5 parts by weight of an organic binder such as a resin mixed to 100 parts by weight of silver powder is used. The organic binder is blended as appropriate for improving the adhesiveness of the layers 14 of the electrode material to the semiconductor substrate 2 and the layers 12 and 13 of the electrode materials. The applied thickness of the paste is adjusted according to the thickness of the extracting electrodes 9 to be formed by firing.

Next, on the antireflective coating 7 on the surface of the semiconductor substrate 2, a paste of an electrode material for forming the front electrode 4 containing silver is printed into a planar shape of the finger electrodes 5 and the bus bar electrodes 6 as the front electrode 4 by means of screen printing or the like and dried to form a layer 15 of the electrode material for forming the front electrode 4 (FIG. 7). As the paste of the electrode material to be used herein, a paste with the same composition as that of the paste used for forming the layers 14 of the electrode material can be used. The applied thickness of the paste is adjusted according to the thickness of the front electrode 4 to be formed by firing.

Next, the semiconductor substrate 2 including the layers 12 through 15 of the electrode materials formed on the surface and the back surface thereof is fired for 10 to 30 minutes at 600 through 800° C. Then, when the layers 12 through 15 of the electrode materials contain an organic binder, the organic binder is thermally decomposed and removed. In addition, aluminum powder and silicon powder in the layers 12 and 13 of the electrode materials are melted and fused and the layers 12 and 13 are melted and fused to form the collecting electrode 10.

In addition, from the layer 13 of the electrode material, aluminum is thermally diffused into the layer 12 of the electrode material, and from the layer 12 of the electrode material, aluminum is thermally diffused into the back side of the semiconductor substrate 2 to form the BSF region 11 on the back side. Along with this, the semiconductor substrate 2 and the collecting electrode 10 are conductively connected to each other. Furthermore, from the back side of the semiconductor substrate 2, silicon is thermally diffused into the layer 12 of the electrode material, and from the layer 12 of the electrode material, silicon is thermally diffused into the layer 13 of the electrode material. Therefore, the collecting electrode 10 has a silicon distribution in which the content ratio of silicon becomes higher in the side of the collecting electrode in contact with the semiconductor substrate than in the outer surface side. Thermal expansion coefficients of the back side of the semiconductor substrate 2 and the side of the collecting electrode in contact with the semiconductor substrate become closer to each other.

By adjusting the firing conditions, etc., the degree of thermal diffusion of aluminum and silicon can be changed. Therefore, the content ratio of silicon in the collecting electrode 10 can be adjusted to an arbitrary distribution form from a distribution form in which the content ratio is continuously and monotonously reduced from the side in contact with the semiconductor substrate 2 toward the outer surface side, through a distribution form in which the content ratio is discontinuously and monotonously reduced from the side in contact with the semiconductor substrate 2 toward the outer surface side, and to a distribution form in which the content ratio is monotonously reduced stepwise from the side in contact with the semiconductor substrate 2 toward the outer surface side.

By the firing, silver powder in the layer 14 of the electrode material is melted and fused to form the extracting electrodes 9, and the extracting electrodes 9 are melted and fused with and conductively connected to the collecting electrode 10. Simultaneously, the silver powder in the layer 15 of the electrode material is melted and fused while penetrating the antireflective coating 7 to form the front electrode 4 which is conductively connected to the diffusion layer 3 of the semiconductor substrate 2 (fire through method). However, the front electrode 4 may be formed by firing the layer 15 of the electrode material for forming the front electrode 4 after forming this layer 15 by exposing the surface of the diffusion layer 3 of the semiconductor substrate 2 by etching and removing the antireflective coating 7 in the region corresponding to the planar shape of the surface side electrode 4. By performing cooling after firing, the solar cell device 1 is completed.

At this time, the thermal expansion coefficient of the side of the collecting electrode 10 in contact with the semiconductor substrate 2 is adjusted by making silicon contained in aluminum, so that the difference in the contracting amounts between the semiconductor substrate 2 and the collecting electrode 10 due to the difference in the thermal expansion coefficients is reduced and the warping of the solar cell device 1 can be reduced. In addition, when firing, from the layer 12 of the electrode material, aluminum is smoothly thermally diffused into the back side of the semiconductor substrate 2 and the BSF region 11 with a uniform and sufficient thickness is formed on the back side, and the content ratio of silicon in the collecting electrode 10 is set smaller in the outer surface side and a rise in the content ratio of silicon in the whole of the collecting electrode 10 is suppressed to maintain the conductivity in a good range, so that the characteristics of the solar cell device 1 can be improved. According to the above-described manufacturing method, only one time of firing is enough, so that the production yield of the solar cell device 1 can be improved. However, for example, it is also possible that a plurality of times of firing are performed such that the back electrode 8 is formed by the first firing and the front electrode 4 is formed by the second firing.

It is preferable that the thickness of the collecting electrode 10 is 10 to 30 μm. For example, when the collecting electrode 10 is formed by firing the two layers 12 and 13 of the electrode materials, if the thickness of the collecting electrode 10 is less than 10 μm, the thicknesses of the layers 12 and 13 of the electrode materials both become small, so that the effect of suppressing a rise in the content ratio of silicon in the whole of the collecting electrode 10 and maintaining the conductivity thereof in a good range becomes insufficient, and when firing the layers 12 and 13 of the electrode materials, the amount of aluminum thermally diffused into the back side of the semiconductor substrate 2 is reduced, and it becomes impossible to form the BSF region 11 with a uniform and sufficient thickness on the back side, so that the characteristics of the solar cell device 1 may deteriorate.

If the thickness of the collecting electrode 10 is more than 30 μm, even by employing the construction of the present invention, the effect of reducing the warping of the solar cell device 1 cannot be sufficiently obtained particularly when the thickness of the semiconductor substrate 2 is set to be not more than 300 μm, and the solar cell device 1 may greatly warp.

According to the present invention, the thickness of the collecting electrode 10 is obtained as follows by using a non-contact measuring method using an infrared ray, a laser, etc. That is, an inner region of the collecting electrode 10 except for the range of about 5 mm from the outer peripheral portion is equally divided (for example, into an equal 6 sections), and a total thickness including the semiconductor substrate 2 at an arbitrary position in each section is measured by the non-contact measuring method using an infrared ray, a laser, etc. Next, an average of the measured values is calculated, and a value obtained by subtracting the thickness of the semiconductor substrate 2 from this average is determined as the thickness of the collecting electrode 10. The thickness of the semiconductor substrate 2 may be measured before forming the collecting electrode 10, or the collecting electrode 10 is formed and the total thickness is measured by the above-described method, and thereafter at least a part of the collecting electrode 10 is peeled off and measured. Furthermore, a thickness in a region in which the collecting electrode 10 is not formed in the semiconductor substrate 2 may be measured. In all methods, the result is the same.

When the collecting electrode 10 is formed by firing the two layers 12 and 13 of the electrode materials, the thicknesses of both layers 12 and 13 of the electrode materials are preferably not less than 5 μm. If the thickness of the layer 12 of the electrode material is less than 5 μm, when firing, the amount of aluminum to be thermally diffused into the back side of the semiconductor substrate 2 from the layer 12 of the electrode material is reduced and it becomes impossible to form the BSF region 11 with a uniform and sufficient thickness on the back side, so that the characteristics of the solar cell device 1 may deteriorate. If the thickness of the layer 13 of the electrode material is less than 5 μm, the effect of suppressing a rise in the content ratio of silicon in the whole of the collecting electrode 10 and maintaining the conductivity of the collecting electrode 10 in a good range becomes insufficient, so that the characteristics of the solar cell device 1 may deteriorate.

The collecting electrode 10 may be formed by firing three or more layers of electrode materials. In this case, the layer of the electrode material on the side in contact with the semiconductor substrate 2 is composed similarly to the layer 12 of the electrode material, and the layer of the electrode material on the outermost surface side is composed similarly to the layer 13 of the electrode material. Thereby, in the collecting electrode 10 formed by firing three or more layers of the electrode materials, the content ratio of silicon is set higher in the side in contact with the semiconductor substrate 2 than in the outer surface side.

The content ratio of silicon in the middle layer of the electrode material to be disposed between the above-described two layers of the electrode materials is preferably an intermediate value of the content ratios of silicon in the layer of the electrode material on the side in contact with the semiconductor substrate 2 and in the layer of the electrode material on the outermost surface side. In this case, the content ratio of silicon is monotonously reduced from the side in contact with the semiconductor substrate 2 toward the outer surface side. However, the content ratio of silicon in the middle layer of the electrode material may be higher than the content ratio of silicon in the layer of the electrode material on the side in contact with the semiconductor substrate 2, or may be smaller than the content of silicon in the layer of the electrode material on the outermost surface side. In the former case, the effect of reducing the warping of the solar cell can be further improved, and in the latter case, the characteristics of the solar cell can be further improved.

The construction of the present invention is not limited to the examples of the drawings described above, and the design can be variously changed without deviating from the spirit of the present invention. For example, the construction of the present invention is also applicable to a solar cell device using a germanium substrate as the semiconductor substrate.

### EXAMPLES

### Examples 1 to 7

### Preparation of Semiconductor Substrate 2

A polycrystal silicon ingot produced by the casting method was sliced to form a polycrystal silicon substrate as a semiconductor substrate 2 in a plate shape with a size of a 150 mm square and a thickness of 250 μm, and a specific resistance of 1.5 Ω·cm, and its entire surface was etched with alkali to remove damaged layers, and the surface was cleaned and dried. Then, the semiconductor substrate 2 was set in a diffusion furnace and heated in the presence of phosphorus oxychloride to diffuse phosphorus as an n-type impurity into the entire surface, and then the diffusion layer formed on the side surface and back surface of the semiconductor substrate 2 was removed to form the diffusion layer 3.

The diffused amount of phosphorus in the diffusion layer 3 was 1×10¹⁷ atoms/cm³ in terms of the number of atoms (atoms/cm³) of phosphorus as an n-type impurity per unit volume, and the sheet resistance of the surface of the diffusion layer 3 was 45Ω/□. On the entire surface of the semiconductor substrate 2 on which the diffusion layer 3 was formed, a silicon nitride film with a refractive index of 1.9 and a thickness of 850 Å as the antireflective coating 7 was formed by the plasma CVD method using a mixed gas of silane (SiH₄), ammonia (NE₃) and hydrogen (H₂).

(Formation of Layer 12 of Electrode Material)

Here, 100 parts by weight of aluminum powder, 30 parts by weight of silicon powder, 20 parts by weight of an organic solvent, and 3 parts by weight of an organic binder were mixed to prepare a paste for forming the layer 12 of the electrode material, and the paste was printed by screen printing on the back surface of the semiconductor substrate 2 and dried to form the layer 12 of the electrode material. The thickness of the layer 12 of the electrode material was adjusted to the values indicated in Table 1.

(Formation of Layer 13 of Electrode Material)

Here, 100 parts by weight of aluminum powder, 20 parts by weight of an organic solvent, and 3 parts by weight of an organic binder were mixed to prepare a paste for forming the layer 13 of electrode material, and the paste was printed by screen printing on the layer 12 of the electrode material and then dried to laminate the layer 13 of the electrode material. The thickness of the layer 13 of the electrode material was adjusted to the values indicated in Table 1.

(Formation of Layers 14 and 15 of Electrode Material)

Here, 100 parts by weight of silver powder, 20 parts by weight of an organic solvent, and 3 parts by weight of an organic binder were mixed to prepare a paste for forming the layers 14 and 15 of the electrode material, and the paste was printed by screen printing on the back surface of the semiconductor substrate 2 and dried to form the layers 14 of the electrode material which become the extracting electrodes 9 in planar shapes shown in FIG. 2. Furthermore, the paste was printed by screen printing on the antireflective coating 7 on the surface of the semiconductor substrate 2 and dried to form the layer 15 of the electrode material which becomes the front electrode 4 in a planar shape shown in FIG. 1.

(Firing)

The semiconductor substrate 2 on which the layers 12 through 15 of the electrode materials were formed was put into an infrared firing furnace and fired by being heated for 15 minutes at 750° C. to manufacture the solar cell device 1 having the form shown in FIG. 1 through FIG. 3.

### Examples 8 to 12

Solar cell devices 1 having the form shown in FIG. 1 through FIG. 3 were manufactured in the same manner as in the Examples 1, 3 and Examples 5 to 7 except that 100 parts by weight of aluminum powder, 10 parts by weight of silicon powder, 20 parts by weight of an organic solvent, and 3 parts by weight of an organic binder were mixed, prepared, and used as a paste for forming the layer 13 of the electrode material.

### Examples 13 to 17

Solar cell devices 1 having the form shown in FIG. 1 through FIG. 3 were manufactured in the same manner as in the Example 6 except that 100 parts by weight of aluminum powder, amounts indicated in Table 1 of silicon powder, 20 parts by weight of an organic solvent, and 3 parts by weight of an organic binder were mixed, prepared, and used as a paste for forming the layer 12 of the electrode material.

### Comparative Examples 1 to 5

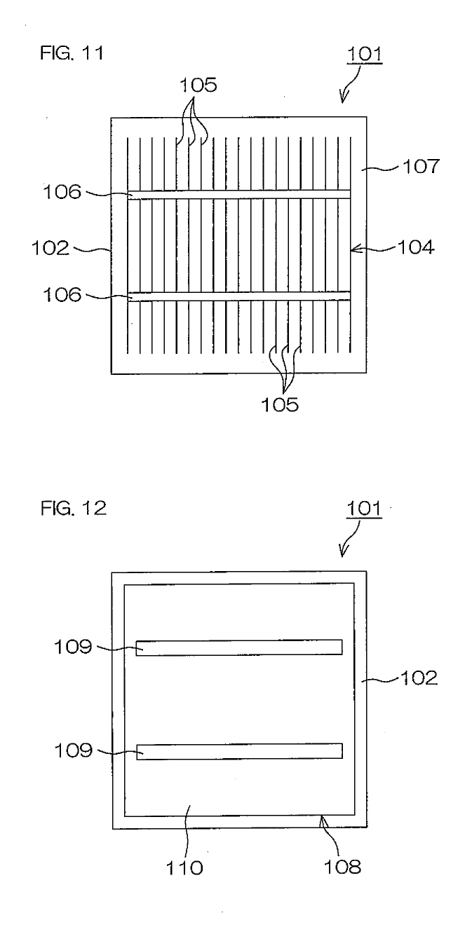

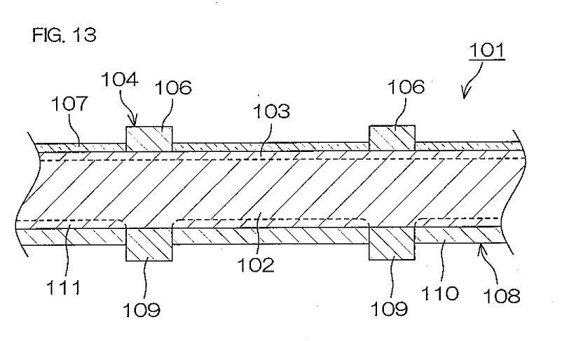

Solar cell devices 101 having the form shown in FIG. 11 through FIG. 13 were manufactured in the same manner as in the Examples 1 to 17 except that a paste was prepared by mixing 100 parts by weight of aluminum powder, 20 parts by weight of an organic solvent, 3 parts by weight of an organic binder and the paste was printed by screen printing on the back surface of the semiconductor substrate 2 and then dried to form a single layer of the electrode material that becomes the collecting electrode 110 in the planar shape shown in FIG. 12. The applied thickness of the paste was adjusted so that the thickness of the collecting electrode 110 to be formed by firing became the values indicated in Table 2.

### Comparative Examples 6 to 10

Solar cell devices 101 having the form shown in FIG. 11 through FIG. 13 were manufactured in the same manner as in the Comparative Examples 1 to 5 except that, as a paste for forming the layer of the electrode material, 100 parts by weight of aluminum powder, 30 parts by weight of silicon, 20 parts by weight of an organic solvent, and 3 parts by weight of an organic binder were mixed, prepared, and used.

The characteristics of the solar cell devices manufactured in the respective Examples and Comparative Examples were evaluated through the following tests.

<Measurement of Conversion Efficiency>

From the results of current-voltage measurement by irradiating surfaces of the solar cell devices manufactured in the Example or Comparative Example with light with an AM of 1.5, the conversion efficiency Effi (%) was obtained.

<Measurement of Warping Amount>

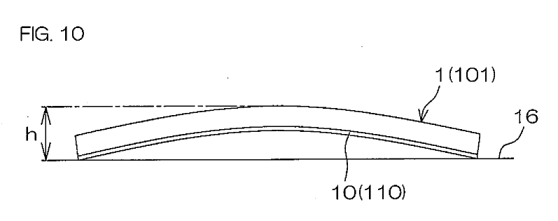

As shown in FIG. 10, the maximum height h (mm) of the solar cell device 1 (101) manufactured in the Example or the Comparative Example, placed on a flat board 16 by setting the side of the collecting electrode 10 (110) down, was measured as a warping amount of the solar cell device 1 (101).

<Measurement of Thickness of Collecting Electrode>

In the collecting electrode of the solar cell device manufactured in the Example or Comparative Example, the inner region except for the range of about 5 mm from the outer peripheral portion was divided into an equal six sections, and a total thickness including the semiconductor substrate at an arbitrary position in each section was measured by using an infrared thickness measuring device. Next, an average of the measured values was calculated, and a value obtained by subtracting the thickness of the semiconductor substrate measured in advance from this average was determined as the thickness of the collecting electrode.

The results are shown in Table 1 and Table 2.

TABLE 1

| | Collecting electrode | | | | | | |
|---|---|---|---|---|---|---|---|
| | | Electrode material | | Electrode material | | | |
| | | layer 12 | | layer 13 | | | |
| | | Silicon content | | Silicon content | | Conversion | |
| | Thickness | ratio (parts by | Thickness | ratio (parts by | Thickness | efficiency | Warping amount |
| | (μm) | weight) | (μm) | weight) | (μm) | (%) | (mm) |
| Example 1 | 8 | 30 | 4 | 0 | 4 | 14.3 | 0.5 |
| Example 2 | 10 | 30 | 3 | 0 | 7 | 15.0 | 0.7 |
| Example 3 | 10 | 30 | 5 | 0 | 5 | 15.2 | 0.7 |
| Example 4 | 10 | 30 | 7 | 0 | 3 | 15.0 | 0.6 |
| Example 5 | 20 | 30 | 10 | 0 | 10 | 15.4 | 0.9 |
| Example 6 | 30 | 30 | 15 | 0 | 15 | 15.3 | 1.3 |
| Example 7 | 35 | 30 | 20 | 0 | 20 | 15.4 | 1.5 |
| Example 8 | 8 | 30 | 4 | 10 | 4 | 14.4 | 0.5 |
| Example 9 | 10 | 30 | 5 | 10 | 5 | 15.1 | 0.7 |
| Example 10 | 20 | 30 | 10 | 10 | 10 | 15.3 | 0.9 |
| Example 11 | 30 | 30 | 15 | 10 | 15 | 15.3 | 1.2 |
| Example 12 | 35 | 30 | 20 | 10 | 20 | 15.3 | 1.4 |
| Example 13 | 30 | 0.3 | 15 | 0 | 15 | 15.1 | 1.4 |
| Example 14 | 30 | 0.5 | 15 | 0 | 15 | 15.2 | 1.3 |
| Example 15 | 30 | 10 | 15 | 0 | 15 | 15.4 | 1.3 |
| Example 16 | 30 | 50 | 15 | 0 | 15 | 15.2 | 1.2 |
| Example 17 | 30 | 55 | 15 | 0 | 15 | 15.0 | 1.2 |

TABLE 2

| | Collecting electrode | | | |
|---|---|---|---|---|
| | | Silicon content | | |
| | Thickness | ratio (parts by | Conversion | Warping amount |
| | (μm) | weight) | efficiency (%) | (mm) |
| Comparative Example 1 | 10 | 0 | 12.5 | 0.8 |
| Comparative Example 2 | 20 | 0 | 14.0 | 0.9 |
| Comparative Example 3 | 30 | 0 | 14.7 | 1.4 |
| Comparative Example 4 | 40 | 0 | 15.2 | 1.7 |
| Comparative Example 5 | 50 | 0 | 15.3 | 2.0 |
| Comparative Example 6 | 10 | 30 | 14.1 | 0.7 |
| Comparative Example 7 | 20 | 30 | 14.4 | 0.9 |
| Comparative Example 8 | 30 | 30 | 14.8 | 1.2 |
| Comparative Example 9 | 40 | 30 | 15.2 | 1.6 |
| Comparative Example 10 | 50 | 30 | 15.4 | 1.8 |

Referring to Table 2, it was found that, among the conventional solar cell devices of the Comparative Examples 1 to 5 including collecting electrodes made of aluminum that do not contain silicon and the solar cell devices of the Comparative Examples 6 to 10 including collecting electrodes made of aluminum whose content ratios of silicon were constant in the thickness direction described in Patent document 1, devices with conversion efficiency not less than 15% had warping amounts as large as 1.6 mm or more, and in contrast, the devices having warping amounts less than 1.6 mm had conversion efficiencies as small as less than 15%. From these results, it was confirmed that a solar cell device having excellent characteristics while suppressing warping could not be obtained by the conventional constructions.

Referring to Table 1, it was found that the solar cell devices of the Examples 1 to 17 having the construction of the present invention were improved in both warping amount and conversion efficiency than the Comparative Examples. Among the Examples, by comparing the Examples 1 to 7 and the Examples 8 to 12, it was found that in the Examples 2 to 6 and the Examples 9 to 11, the warping amounts were as small as 1.3 mm or less and the conversion efficiencies were as large as 15% or more. From these results, it was confirmed that the thickness of the collecting electrode in the range of 10 to 30 μm was preferable. By comparing the Examples 2 to 4, it was found that the conversion efficiency was highest in the Example 3. By comparing the Examples 8 and 9, it was found that the conversion efficiency was higher in the Example 9. From these results, it was confirmed that the thicknesses of the layers 12 and 13 of the electrode materials were preferably not less than 5 μm.

By comparing the Examples 13 to 17, it was found that the conversion efficiencies were higher in the Examples 14 to 16. From these results, it was confirmed that the content ratio of silicon in the inner region was preferably 0.5 to 50 parts by weight. As evaluation after firing, the concentrations of silicon in the thickness direction of the collecting electrodes of the solar cell devices of the Examples 5, 6, 10 and Examples 14 to 16 were measured by using an X-ray micro analyzer (EPMA), and it was confirmed that the concentration of silicon was discontinuously and monotonously reduced from the side in contact with the semiconductor substrate toward the outer surface side in all devices.

1-7. (canceled)

8. A solar cell device comprising: a planar semiconductor substrate having a front surface and a back surface; an electrode provided on generally entire area of the back surface of the semiconductor substrate, wherein at least a part in a thickness direction of the electrode contains a semiconductor element constituting the semiconductor substrate, and a content ratio of the semiconductor element in the electrode is set greater in an inner region which is closer to the semiconductor substrate than in an outer region which is opposite to the inner region.

9. The solar cell device according to claim 8, wherein the back side of the semiconductor substrate has a BSF region.

10. The solar cell device according to claim 9, wherein the content ratio of the semiconductor element in the electrode is discontinuously changed in the thickness direction of the electrode.

11. The solar cell device according to claim 10, wherein the content ratio of the semiconductor element in the electrode is discontinuously and monotonously reduced from the side in contact with the semiconductor substrate toward the outer surface side.

12. The solar cell device according to claim 9, wherein the electrode is formed by laminating two or more electrode materials with different content ratios of the semiconductor element in order on generally entire area of the back surface of the semiconductor substrate and firing these.

13. The solar cell device according to claim 9, wherein the semiconductor substrate is a silicon substrate, and the electrode is an aluminum electrode.

14. The solar cell device according to claim 9, wherein a thickness of the electrode is 10 to 30 μm.

15. The solar cell device according to claim 14, wherein a thickness of the semiconductor substrate is not more than 300 μm.

16. A solar cell device comprising: a planar semiconductor substrate having a front surface and a back surface; a collecting electrode provided on generally entire area of the back surface of the semiconductor substrate; and an extracting electrode in a strip shape formed at least in a part on the collecting electrode, wherein at least a part in a thickness direction of the collecting electrode contains a semiconductor element constituting the semiconductor substrate, and a content ratio of the semiconductor element in the collecting electrode is set greater in an inner region which is closer to the semiconductor substrate than in an outer region which is closer to the extracting electrode.

17. A method for manufacturing a solar cell device, comprising the steps of: forming a lamination of two or more electrode materials with different content ratios of a semiconductor element by applying in order a paste of two or more electrode materials with different content ratios of the semiconductor element on generally entire area of a back surface of a planar semiconductor substrate having a front surface and the back surface and drying these; and forming an electrode by firing and unifying the lamination.

18. The solar cell device according to claim 17, wherein the content ratios of the semiconductor element in a layer of the electrode materials in contact with the back surface of the semiconductor substrate is set to 0.5 through 50 parts by weight based on 100 parts by weight of the electrode materials.
